(19) United States
(12) Patent Application Publication
(10) Pub. No.: US 2010/0117153 A1
(43) Pub. Date: May 13, 2010

(54) HIGH VOLTAGE SOI CMOS DEVICE AND METHOD OF MANUFACTURE

(75) Inventors: Thomas B. Lucking, Maple Grove, MN (US); Thomas R. Keyser, Plymouth, MN (US); Paul S. Fechner, Plymouth, MN (US)

Correspondence Address: HONEYWELL/S&S;Patent Services, 101 Columbia Road, P.O.Box 2245, Morristown, NJ, 07962-2245, US

(73) Assignee: HONEYWELL INTERNATIONAL INC., Morristown, NJ (US)

(21) Appl. No.: 12/267,310

(22) Filed: Nov. 7, 2008

(51) Int. Cl. H01L 27/12; H01L 21/84

(52) U.S. Cl. 257/351; 438/154; 257/E21.7; 257/E27.112

(57) ABSTRACT

A high voltage FET and process for fabricating such an FET are provided. An extended drain and thick gate oxide device design is implemented in a basic CMOS structure to enable higher operating voltages. The basic concept of the invention is well suited for the body-tie architecture often utilized in this technology and is also applicable to other SOI processes using similar isolation schemes.

### FIELD OF INVENTION

The present invention relates to Silicon on Insulator (SOI) Complementary Metal-Oxide Semiconductor (CMOS) fabrication processes, and more particularly, to SOI CMOS fabrication processes that yield devices with higher reliable operating voltage ranges.

### BACKGROUND

Field Effect Transistor (FET) devices that are fabricated using conventional sub-micron (e.g. 150 nm) SOI CMOS processes have a limited reliable operating voltage range. While the limited reliable operating voltage range may be sufficient for certain low power electronic devices, there are many applications that require the switching of voltages beyond the reliable operating voltage range of conventional FET devices. Several of these applications, such as actuators and sensors, further require a direct interface between the FET devices in the circuitry and input signals from an external source.

For such applications that require switching voltages beyond the limited reliable operating voltage ranges, conventional Metal-Oxide Semiconductor Field Effect Transistor (MOSFET) devices are typically stacked to provide the necessary switching voltage potentials. While stacking MOSFET devices may remedy the issue of limited reliable operating voltage ranges, it also requires additional and potentially complicated circuitry. The additional space required and the potentially complicated circuitry needed makes this method less than ideal, particularly when a direct interface between the device and input signals is required. Another method to provide the necessary voltage potential range may be to develop and fabricate devices that provide for the specific voltage needs of the application. However, such devices are often expensive and the fabrication processes devised for such devices are not versatile.

As such, an inexpensive MOSFET device with the ability to handle the switching of larger voltage signals is desired.

### SUMMARY

The embodiments described herein address the issue of limited reliable voltage ranges by incorporating novel extended drain and thick gate oxide device designs in a basic CMOS structure to enable higher operating voltages. The basic concept of the invention is well suited for the body-tie architecture often utilized in this technology and is also applicable to other SOI processes using similar isolation schemes.

### BRIEF DESCRIPTION OF FIGURES

FIGS. 1a-1c are cross-section diagrams illustrating the initial steps of an SOI CMOS fabrication process, according to an embodiment of the present invention.

FIGS. 2a-2l are cross-section diagrams illustrating the steps of an SOI CMOS fabrication process to follow the steps shown in FIG. 1a-1c, according to an embodiment of the present invention.

FIG. 3 is a cross-section diagram illustrating an SOI device fabricated by an SOI CMOS process, according to an embodiment of the present invention.

FIG. 4 is a cross-section diagram illustrating the SOI device in FIG. 3 in operation, according to an embodiment of the present invention.

FIGS. 5a-5m are cross-section diagrams illustrating the steps of an SOI CMOS fabrication process to follow the steps shown in FIG. 1a-1c, according to an embodiment of the present invention.

FIG. 6 is a cross-section diagram illustrating a high voltage device fabricated by an SOI CMOS process, according to an embodiment of the present invention.

FIG. 7 is a cross-section diagram illustrating the high voltage device of FIG. 6 in operation, according to an embodiment of the present invention.

FIG. 8 is a cross-section diagram illustrating the high voltage device of FIG. 6 in operation, according to an embodiment of the present invention.

### DETAILED DESCRIPTION

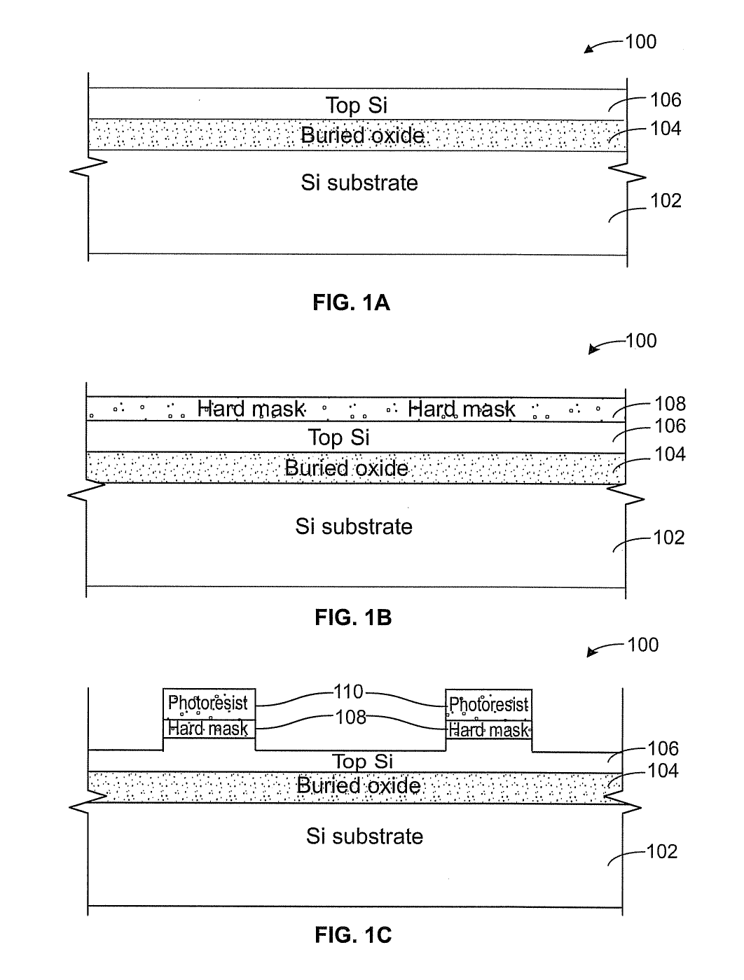

FIG. 1a shows a standard SOI stack 100 comprising a top silicon layer 106 overlaying a buried oxide layer 104, which overlays a silicon substrate 102. FIG. 1b shows the SOI stack 100 further comprising a hard mask layer 108 overlaying the top silicon layer 106. FIG. 1c shows the SOI stack 100 after selective removal of the hard mask layer 108 and portions of the top silicon layer 106 via the use of a patterned photoresist 110. In this exemplary embodiment, the selective removal of the hard mask layer 108 and portions of the top silicon layer 106 results in two protruding island structures. Henceforth, components consistent between figures will have the same reference numerals.

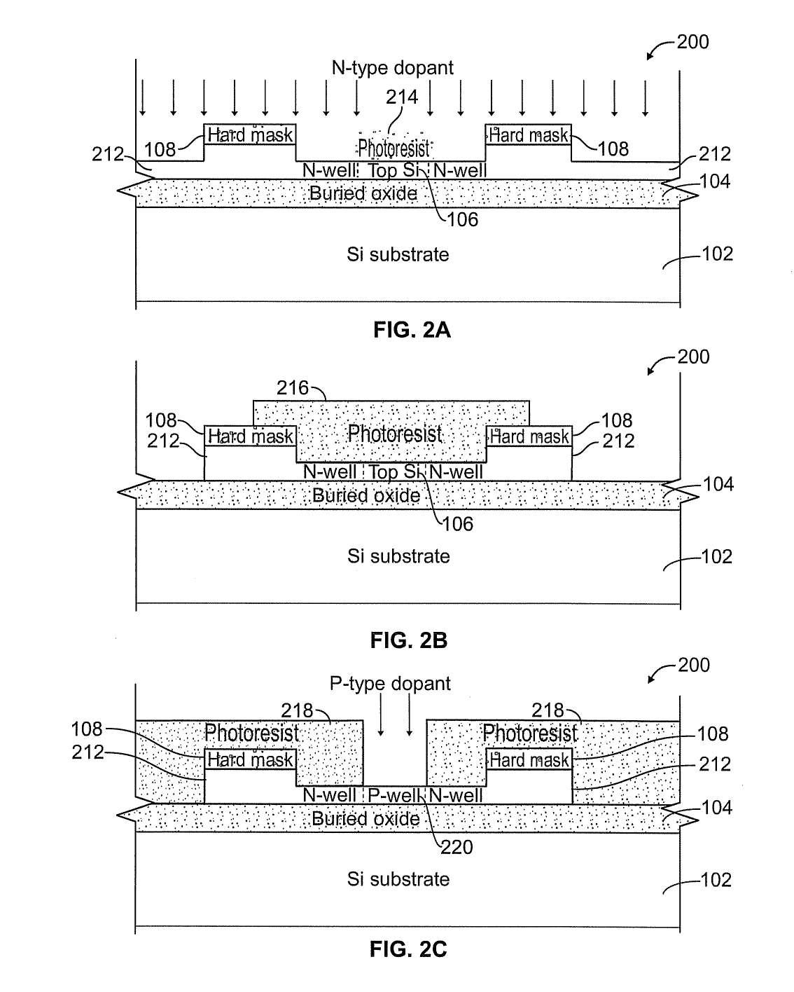

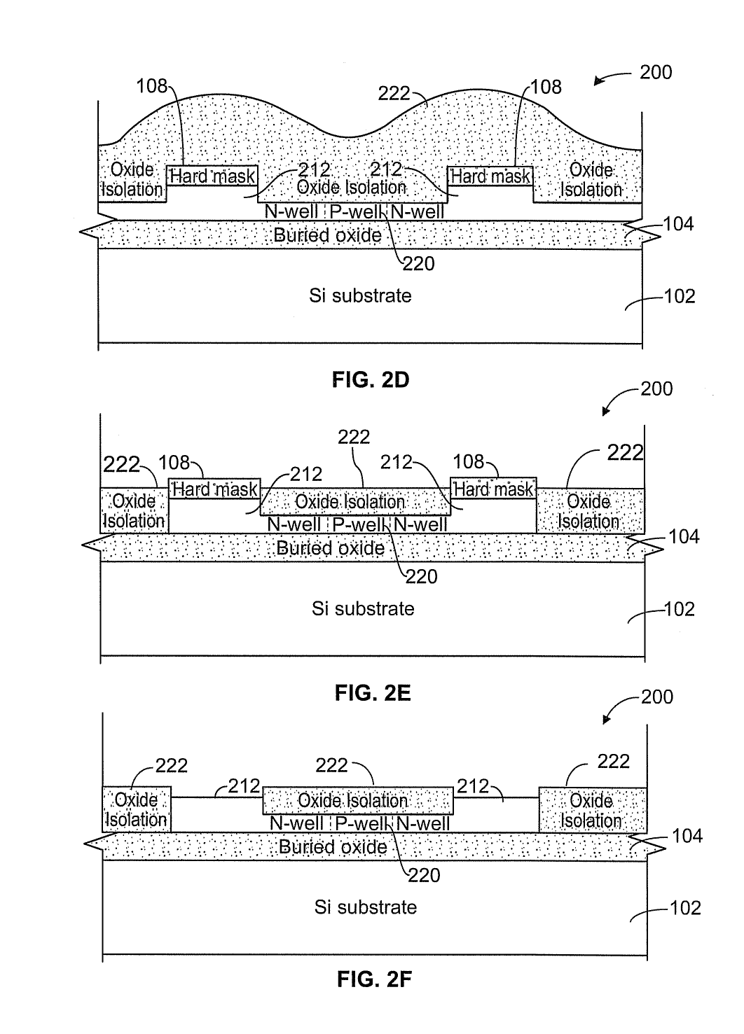

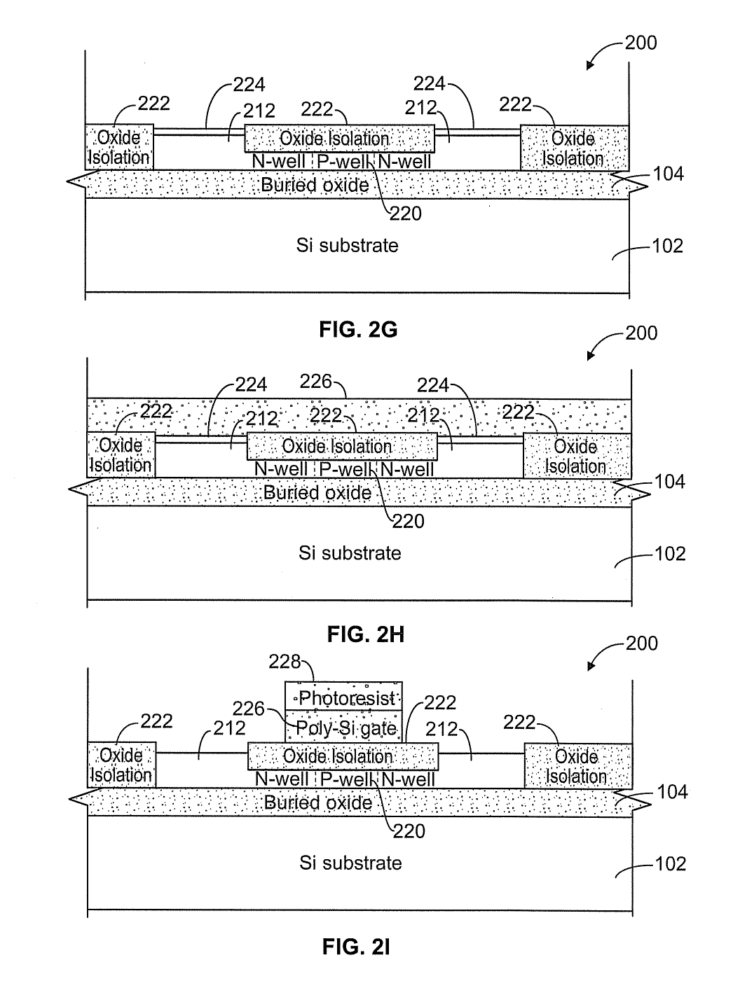

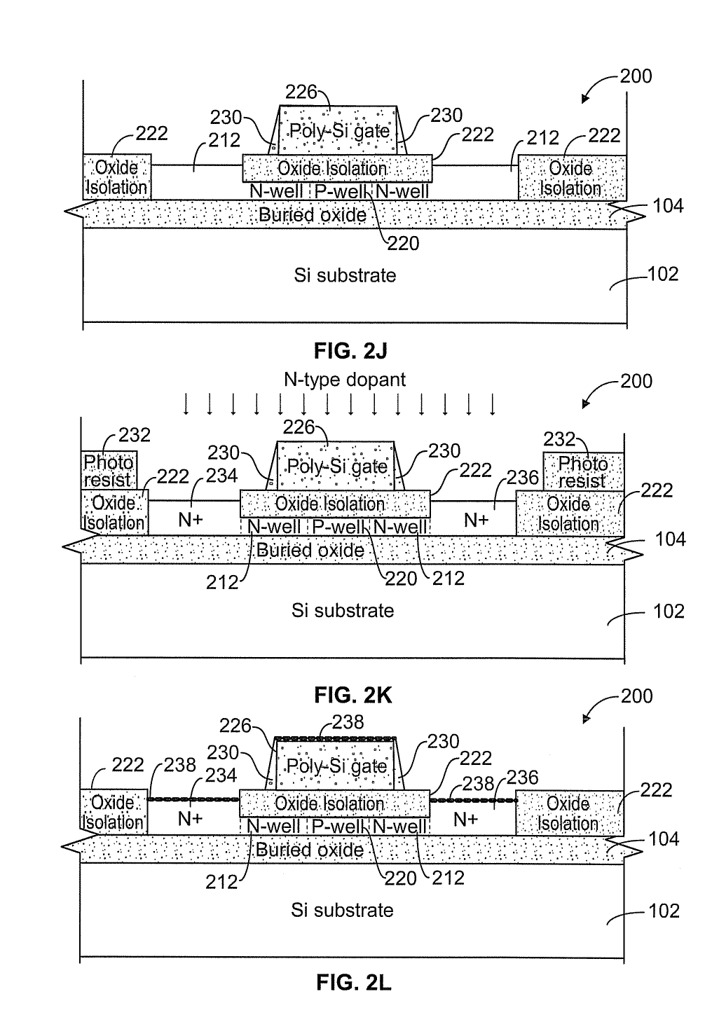

FIGS. 2a-21 are cross-section diagrams illustrating steps of an SOI CMOS fabrication process to follow the steps in FIG. 1a-1c, according to an embodiment of the present invention. The architectural characteristics of a device fabricated this way make the process well-suited for body-tie applications. The SOI structure 200 is the SOI stack 100 of FIG. 1a-1c after further fabrication.

FIG. 2a shows a masked N-well implant, where a patterned photoresist 214 is provided to cover a portion of the top silicon layer 106 during N-type doping, resulting in the creation of N-wells 212 from the exposed portions of the top silicon layer 106, while leaving the portion of the top silicon layer 106 under the photoresist 214 relatively untouched. In this exemplary embodiment, the covered portion of the top silicon layer 106 is between the two protruding structures. The N-type doping can be either a standard N-well implant or a gated body-tie FET specific implant. After removal of the photoresist 214, a second photoresist 216 is provided for the masked removal of portions of N-wells 212 that are not adjacent to the portion of untouched top silicon layer 106 or under the hard mask 108, as shown in FIG. 2b. FIG. 2c shows a masked P-well implant, where a patterned photoresist 218 is provided during P-type doping, resulting in the creation of P-well 220. The photoresist 218 covers most of the SOI structure 200, exposing the previously untouched portion of top silicon layer 106 for doping. This can be either a standard P-well implant or a gated body-tie FET specific implant. Alternatively, the implant could be omitted, leaving the silicon at a native doping level, which would be nearly intrinsic.

FIG. 2d shows the deposition of an isolation oxide 222 covering the entire SOI structure 200. FIG. 2e shows the isolation oxide 222 portions after chemical-mechanical polishing, which lowers the isolation oxide 222 height to a level above the top of the N-wells 212, but below the top of the hard masks 108 such that the hard masks 108 protrude from the polished isolation oxide 222 layer. FIG. 2f shows the removal of the hard masks 108 exposing portions of the N-well 212 below. As such, the polished isolation oxides 222 become the protruding structures in SOI structure 200. One of the protruding polished isolation oxides 222 overlays the P-well 220 and portions of the N-wells 212, and the others of the protruding polished isolation oxides 222 directly overlay the buried oxide layer 104. A gate oxide layer 224 is then grown over the portions of exposed N-wells 212, as shown in FIG. 2g.

FIG. 2h shows the deposition of a poly-silicon layer 226 across the entire SOI structure 200 as the gate layer of the device. In FIG. 2i, a patterned photoresist 228 is provided for the selective removal of portions of the poly-silicon layer 226 to form the gate of the device. The photoresist 228 covers a portion of the poly-silicon 226 overlaying a portion of the polished isolation oxide 222 between the N-wells 212. Note that the gate oxide layer 224 is also removed in this step, once again exposing portions of the N-wells 212. After the patterned photoresist 228 is removed, spacers 230 are formed on the flanks of the poly-silicon gate 226, overlaying portions of the polished isolation oxide 222, as shown in FIG. 2j. The spacers 230 are formed by depositing and etching, and may comprise oxide or nitride, with nitride being preferred.

In FIG. 2k, a patterned photoresist 232 is provided during N-type doping of the exposed N-wells 212, resulting in the creation of an N-type source 234 and N-type drain 236. The photoresist 232 covers portions of the polished isolation oxides 222 directly overlaying the buried oxide layer 104, and in particular, that portion where the silicon doping is not desired. FIG. 2l shows the final processing steps for the SOI structure 200, comprising forming silicide 238 on the exposed silicon N-type source 234, N-type drain 236, and poly-silicon gate 226 for reduced contact resistance, and standard metallization and interconnections.

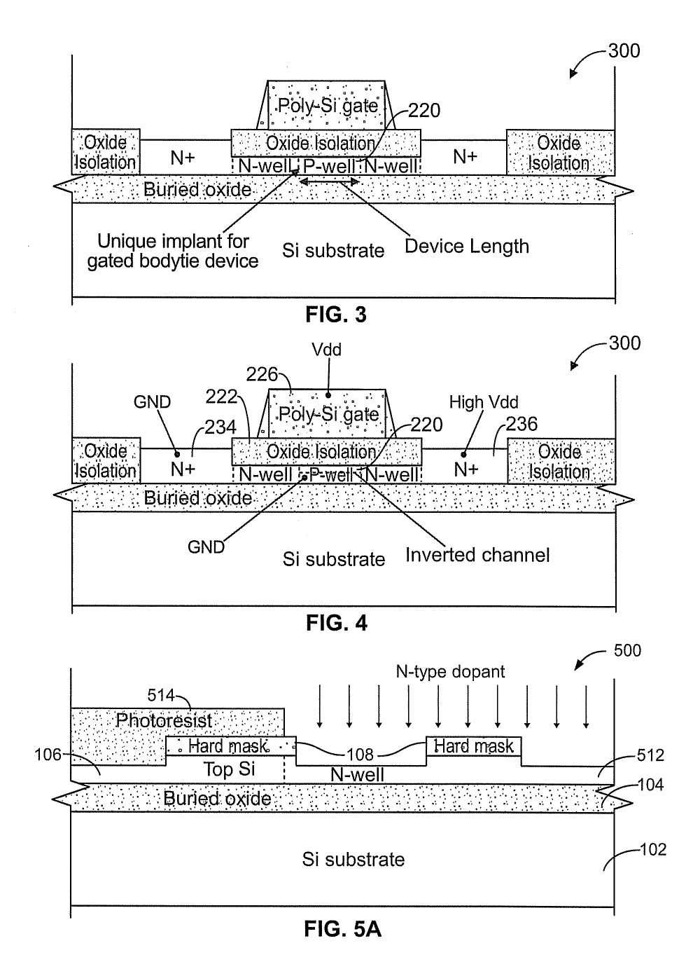

FIG. 3 is a cross-section diagram showing an SOI device 300, which can be used as a high voltage switching device and can be fabricated by the SOI CMOS process detailed above, according to exemplary embodiment of the present invention. Since low doping levels are required to create a high junction breakdown voltage while retaining a reasonable threshold voltage, the device length (i.e. length of the P-well 220) of the SOI device 300 is designed to be of sufficient length to avoid punch-through at the maximum operating voltage intended for the device.

FIG. 4 is a cross-section diagram illustrating the SOI device 300 in operation, according to an embodiment of the present invention. The exemplary configuration of SOI device 300 comprises a ground voltage coupled with the N-type source 234 and the P-well 220, a switching voltage coupled with the poly-silicon gate 226, and a high voltage coupled with the N-type drain 236. As such, an N-type gated body-tie FET device is achieved. The operation of this gated body-tie oxide configuration is similar to that of a standard MOSFET device, with the primary difference being the use of the isolation oxide 222 underlying the poly-silicon gate 226 as the gate oxide equivalent.

Accordingly, the gated body-tie FET device in the present invention can be used to attain higher operating voltages than a standard MOSFET device would otherwise support, and differ from an extended drain device to be discussed below, by being able to handle a high gate voltage in addition to the high drain voltage. Further, this gated body-tie FET device requires minimal changes to the standard CMOS flow, making it a relatively inexpensive device to develop.

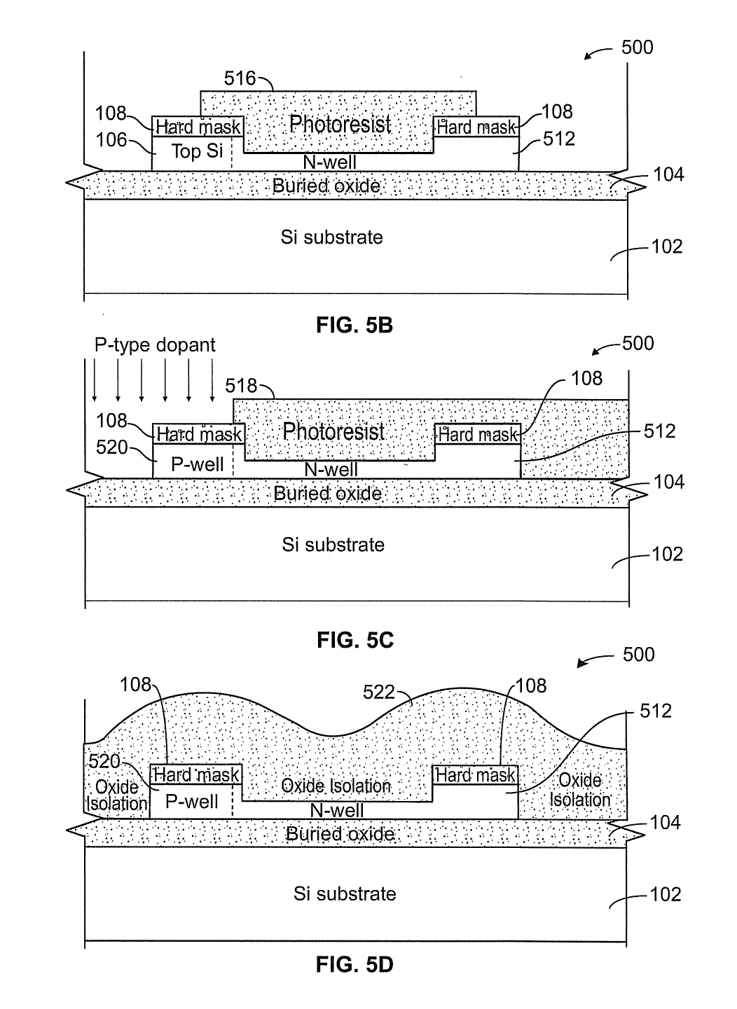

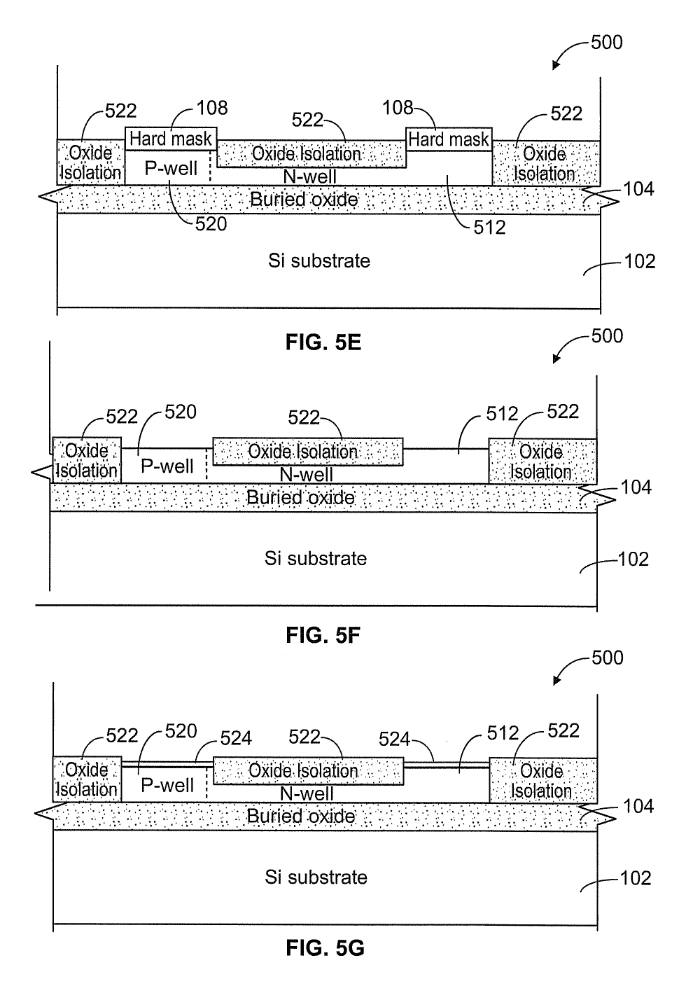

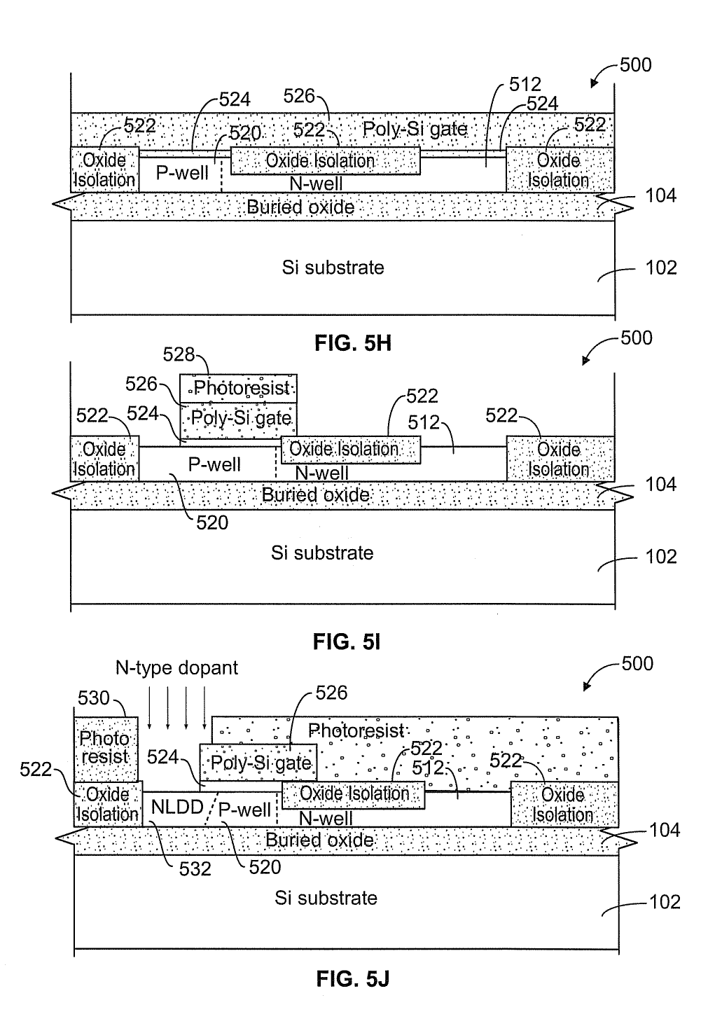

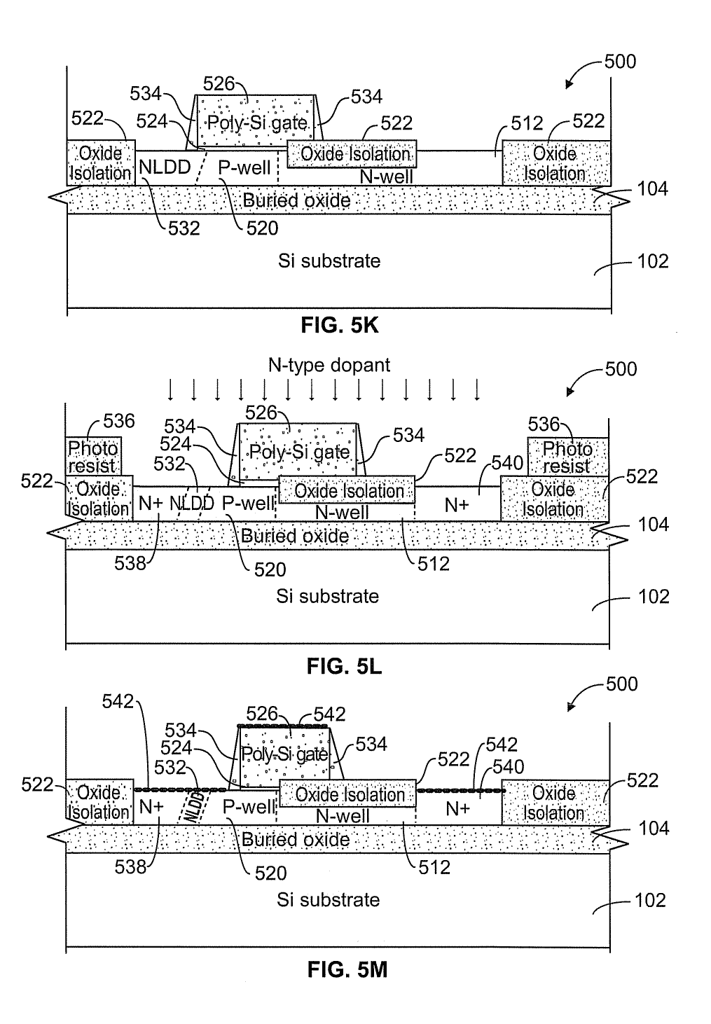

FIGS. 5a-5m are cross-section diagrams illustrating steps of an SOI CMOS fabrication process to follow the steps in FIG. 1a-1c, according to an alternative embodiment of the present invention. The architectural characteristics of a device fabricated this way make the process well-suited for extended drain device applications. The SOI structure 500 is the SOI stack 100 of FIG. 1a-1c after further fabrication.

FIG. 5a shows a masked N-well implant, where a patterned photoresist 514 is provided to cover a portion of the top silicon layer 106 during N-type doping, resulting in the creation of an N-well 512 from the exposed portions of the top silicon layer 106, while leaving the portion of the top silicon layer 106 under the photoresist 514 relatively untouched. In this exemplary embodiment, the photoresist 514 covers a portion of one of the protruding island structures and the outlying portion of the top silicon layer 106 adjacent to the partially covered protruding island structure. The N-type doping can be either a standard N-well implant or an extended drain FET specific implant.

After removal of the photoresist 514, FIG. 5b shows a patterned photoresist 516 provided for the masked removal of portions of the N-well 512 and top silicon layer 106 that do not underlie the hard masks 108 or are not between the two protruding island structures. FIG. 5c shows a masked P-well implant, wherein after the photoresist 516 is removed, a patterned photoresist 518 is provided during P-type doping, resulting in the creation of P-well 520. The photoresist 518 covers the length of the N-well 512, exposing the previously untouched top silicon layer 106 for doping. This can be either a standard P-well implant or an extended drain FET specific implant.

FIG. 5d shows the deposition of an isolation oxide 522 covering the entire SOI structure 500. FIG. 5e shows the isolation oxide 522 portions after chemical-mechanical polishing, which lowers the isolation oxide 522 height to a level above the top of the N-well 512 and P-well 520, but below the top of the hard masks 108 such that the hard masks 108 protrude from the polished isolation oxide 522 layer. FIG. 5f shows the removal of the hard masks 108 exposing portions of the underlying N-well 512 and P-well 520. As such, the polished isolation oxides 522 become the protruding structures in SOI structure 500. One of the protruding polished isolation oxides 522 overlays a portion of the N-well 512, and the others of the protruding polished isolation oxides 522 directly overlay the buried oxide layer 104. For 75 nm technology, the preferred thickness of the protruding polished isolation oxide 522 that overlays a portion of the N-well 512 is approximately 500-1400 Angstroms, and more preferably 600-900 Angstroms, and more preferably 600 Angstroms. A gate oxide layer 524 is then grown over the exposed portions of N-well 512 and the P-well 520, as shown in FIG. 5g.

FIG. 5h shows the deposition of a poly-silicon layer 526 across the entire SOI structure 500 as the gate layer of the device. In FIG. 5i, a patterned photoresist 528 is provided for the selective removal of portions of the poly-silicon layer 526 to form the gate of the device 500. The photoresist 528 covers a portion of the poly-silicon 526 that overlays a portion of the P-well 520, a portion of the N-well 512 adjacent to the P-well 520, and a portion of the polished isolation oxide 522 that overlays a portion of the N-well 512. Note that portions of the gate oxide layer 524 that are not covered by the photoresist 528 are also removed in this step, once again exposing portions of the N-well 512 and P-well 520.

FIG. 5j shows a masked N-type lightly doped drain (NLDD) implant, where after the patterned photoresist 528 is removed, another patterned photoresist 530 is provided to cover a portion of the SOI structure 500 during N-type doping. This N-type doping results in the creation of an NLDD region 532 from the exposed portions of the SOI structure 500. The patterned photoresist 530 overlays the isolation oxides 522 and covers the N-well 512, exposing the portion of the P-well 520 that does not underlie the poly-silicon gate 526 and gate oxide 524. As such, the NLDD region 532 is created from the exposed portion of the P-well 520, while the portion of the P-well underlying the gate oxide 524 and poly-silicon gate 526 remains relatively unchanged.

After the patterned photoresist 530 is removed, spacers 534 are formed on the flanks of the poly-silicon gate 526, over a portion of the polished isolation oxide 522, and over a portion of the NLDD 532 adjacent the P-well 520, as shown in FIG. 5k. The spacers 534 are formed by depositing and etching, and may comprise oxide or nitride, with nitride being preferred.

In FIG. 5l, a patterned photoresist 536 is provided during N-type doping of the exposed N-well 512 and exposed NLDD 532, resulting in the creation of an N-type source 538 and N-type drain 540, while leaving a relatively narrow NLDD 532 underlying one of the spacers 534. The patterned photoresist 536 covers a portion of each of the polished isolation oxides 522 directly overlaying the buried oxide layer 104, and in particular, that portion where the silicon doping is not desired. FIG. 5m shows the final processing steps for the SOI structure 500, comprising forming silicide 542 on the exposed silicon N-type source 538, N-type drain 540, and poly-silicon gate 526 for reduced contact resistance, and standard metallization and interconnections.

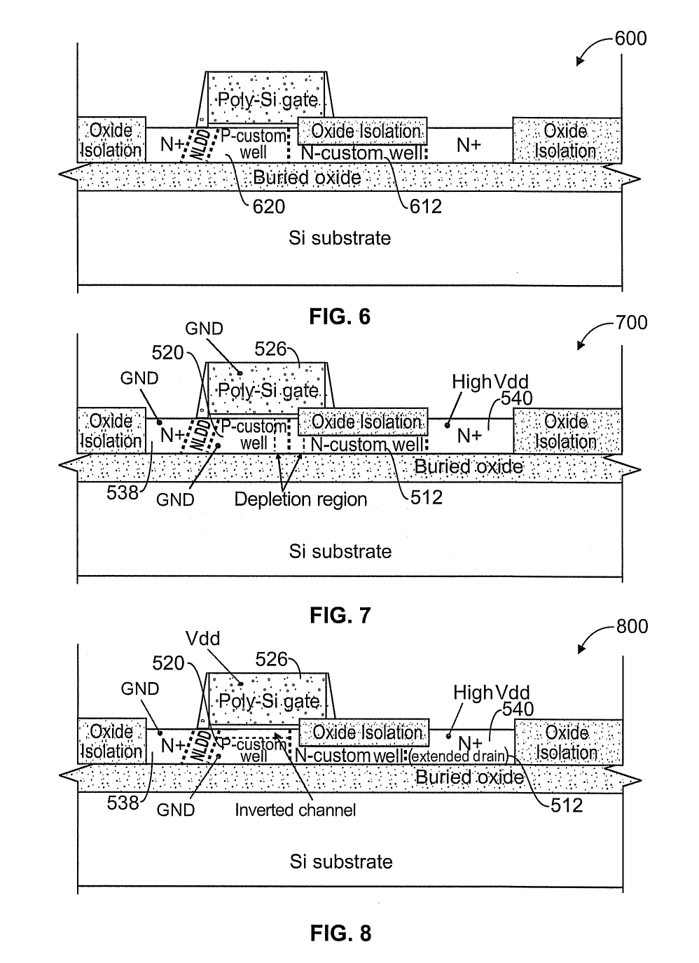

FIG. 6 is a cross-section diagram showing an SOI device 600, which can be used as a high voltage switching device and can be fabricated by an SOI CMOS process detailed above. The implants for P-well 520, N-well 512, or both can alternatively be modified to be extended drain device specific implants to create P-custom 620, N-custom 612 or both respectively to increase the junction breakdown voltage. These specific implants would require additional masks, and require additional processing steps; however, this would allow the specific implants to be individually tailored for the desired device performance. Typically, the tailoring would include reducing the implant dose, in order to achieve a higher junction breakdown voltage.

FIG. 7 is a cross-section diagram illustrating the high voltage device in FIG. 6 in operation, according to an embodiment of the present invention. With a ground voltage coupled to the N-type source 538, P-well 520 and poly-silicon gate 526, and a high voltage coupled to the N-type drain 540, the SOI device 700 represents a device in the “off” state. In this “off” state, a wide depletion region forms around the P-well 520/N-well 512 junction, protecting the thin gate oxide from the elevated voltage.

FIG. 8 is a cross-section diagram illustrating the high voltage device in FIG. 6 in operation, according to an embodiment of the present invention. With a ground voltage coupled to the N-type source 538 and P-well 520, a switching voltage coupled to the poly-silicon gate 526, and a high voltage coupled to the N-type drain 540, the SOI device 800 represents a device in the “on” state. In this “on” state, an inverted channel is created through the P-well 520, and the N-well 512 becomes an extended drain region, acting as a series resistor across which the high voltage drops. The extended drain region must be of sufficient length (given its doping level) to drop sufficient voltage such that the voltage across the gate oxide is low enough to be deemed reliable.

Accordingly, an extended drain FET can be used to attain higher operating voltages than a standard MOSFET would otherwise support due to two features. One is the extended drain region over which the voltage drops during the “on” state of the device. The other is having a drain to body junction between two relatively lightly doped regions that has a high breakdown voltage for handling high voltages during the “off” state of the device. Further, the extended drain FET described above requires minimal changes to the standard CMOS flow, making it a relatively inexpensive device to develop.

Current partially depleted 150 nm SOI technology produces CMOS devices that typically operate at 1.8V and 3.3V. Applying the process described above can accordingly provide higher reliable operating voltages. While certain embodiments have been described, persons of skill in the art will appreciate that variations may be made without departure from the scope and spirit of the invention. The true scope and spirit of the invention is defined by the appended claims, which may be interpreted in light of the foregoing.

We claim:

1. A method for manufacturing a high-voltage gated bodytie field effect transistor, comprising:
depositing a mask over at least a portion of a silicon-on-insulator stack, wherein the silicon-on-insulator stack comprises a silicon substrate, a buried oxide layer, and a silicon device layer;
selectively removing portions of the mask and the silicon device layer to create two protruding islands each having an associated width, wherein a portion of the silicon device layer is left overlaying the buried oxide layer, and wherein the two protruding islands are spaced apart from one another by a distance greater than the width of either of the two protruding islands, thereby increasing device length to avoid punch-through at high source-drain voltages;
implanting dopants into three adjacent wells in the portion of the device layer between the two protruding islands, wherein the three adjacent wells comprise first and second wells doped oppositely to a third well located between the first and second wells;
forming a first portion of an oxide isolation layer over the three adjacent wells and a second portion of the oxide isolation layer adjacent to the two protruding islands opposite the first portion of the oxide isolation layer, wherein the first portion and the second portion are deposited and planarized concurrently, wherein the first portion of the oxide isolation layer serves as a recessed gate oxide during operation of the gated bodytie field effect transistor, and wherein the second portion of the oxide isolation layer is in direct contact with the buried oxide layer to isolate the gated bodytie field effect transistor from any neighboring devices;
forming a poly-silicon gate over the first portion of the oxide isolation layer, wherein the poly-silicon gate is located opposite the third well; and
forming a source and a drain in the silicon device layer, wherein the source and drain are doped oppositely to the third well and similarly to the first and second wells, and wherein the drain and the source each have a thickness greater than that of the first, second, and third wells underlying the recessed gate oxide.

2. The method of claim 1, wherein the recessed gate oxide is approximately 900 Angstroms thick.

3. The method of claim 1, wherein the recessed gate oxide, the source, and the drain have upper surfaces that are substantially coplanar with one another.

4. The method of claim 1, wherein the first and second wells are N-wells, wherein the third well is a P-well, and wherein the source and drain are doped N+.

5. The method of claim 1, wherein the first and second wells are P-wells, wherein the third well is a N-well, and wherein the source and drain are doped P+.

6. The method of claim 1, wherein the gated bodytie field effect transistor is processed concurrently with a second transistor on a common wafer, and wherein the second transistor has a gate oxide that is thinner by at least an order of magnitude than the recessed gate oxide of the gated bodytie field effect transistor.

7. A method for manufacturing a high-voltage extended-drain bodytie field effect transistor, comprising:
depositing a mask over at least a portion of a silicon-on-insulator stack, wherein the silicon-on-insulator stack comprises a silicon substrate, a buried oxide layer, and a silicon device layer;
selectively removing portions of the mask and the silicon device layer to create a first protruding island and a second protruding island, each having an associated width, wherein a portion of the silicon device layer is left overlaying the buried oxide layer;
performing a first-type masked implant on the first protruding island, on at least a center portion of the silicon device layer lying between the first and second protruding islands, and on a first portion of the second protruding island, wherein the first portion is nearest the center portion, thereby forming a first-type well;
performing a second-type masked implant on a second portion of the second protruding island, wherein the second portion is directly adjacent to the first portion, thereby forming a second-type well;
removing portions of the silicon device layer lying outside the first and second islands opposite the center portion;
depositing and planarizing an isolation oxide over the center portion and directly over the buried oxide outside the first and second islands opposite the center portion, thereby surrounding the first and second protruding islands;
removing remaining portions of the mask from the first and second protruding islands to expose portions of the first-type well and the second-type well;
forming a single poly-silicon gate over a first portion of the second-type well, over a portion of the first-type well directly adjacent to the second-type well, and over a portion of the isolation oxide overlying the center portion, wherein forming the single poly-silicon gate includes forming a thin gate oxide; and
forming a source and a drain in the silicon device layer by performing another first-type implant over the exposed portions of the first-type well and the second-type well not overlaid by the poly-silicon gate.

8. The method of claim 7, wherein the extended-drain bodytie field effect transistor is processed concurrently with a second transistor on a common wafer, wherein the extended-drain bodytie field effect transistor and the second transistor each have an associated drain region, and wherein the drain region of the second transistor is shorter than the drain region of the extended-drain bodytie field effect transistor, thereby allowing a higher voltage to be dropped across the drain region of the extended-drain bodytie field effect transistor.

9. The method of claim 7, wherein the isolation oxide over the center portion, the source, and the drain have upper surfaces that are substantially coplanar with one another.

10. The method of claim 7, wherein the isolation oxide over the center portion is approximately 500-1400 Angstroms thick.

11. The method of claim 7, wherein the first-type implants are n-type implants and wherein the second-type implants are p-type implants.

12. The method of claim 7, wherein the first-type implants are p-type implants and wherein the second-type implants are n-type implants.

13. The method of claim 7, further comprising performing an additional first-type masked implant on a second portion of the second-type well, wherein the second portion of the second-type well is directly adjacent to the first portion of the second-type well.

14. A high-voltage gated bodytie field effect transistor, comprising:
a silicon-on-insulator stack comprising a silicon substrate, a buried oxide layer, and a silicon device layer, each having an associated thickness;
two protruding islands in the silicon device layer, each protruding island having an associated width, wherein the two protruding islands are spaced apart from one another by a distance greater than the width of either of the two protruding islands, thereby increasing device length to avoid punch-through at high source-drain voltages, and wherein a portion of the thickness of the silicon device layer between and on either side of the two protruding islands is left overlaying the buried oxide layer;
three adjacent doped wells in the portion of the device layer between the two protruding islands, wherein the three adjacent wells comprise first and second wells doped oppositely to a third well located between the first and second wells;
a first portion of an oxide isolation layer formed over the three adjacent wells, wherein the first portion of the oxide isolation layer serves as a recessed gate oxide during operation of the gated bodytie field effect transistor;
a second portion of the oxide isolation layer formed adjacent to the two protruding islands opposite the first portion of the oxide isolation layer, wherein the first portion and the second portion have upper surfaces that are coplanar, and wherein the second portion of the oxide isolation layer is in direct contact with the buried oxide layer to isolate the gated bodytie field effect transistor from any neighboring devices;
a poly-silicon gate formed over the first portion of the oxide isolation layer, wherein the poly-silicon gate is located opposite the third well; and
a source and a drain formed in the silicon device layer, wherein the source and drain are doped oppositely to the thirdwell and similarly to the first and second wells, and wherein the drain and the source each have a thickness greater than that of the first, second, and third wells underlying the recessed gate oxide.

15. The gated bodytie field effect transistor of claim 14, wherein the recessed gate oxide is approximately 900 Angstroms thick.

16. The gated bodytie field effect transistor of claim 14, wherein the recessed gate oxide, the source, and the drain have upper surfaces that are substantially coplanar with one another.

17. The gated bodytie field effect transistor of claim 14, wherein the first and second wells are N-wells, wherein the third well is a P-well, and wherein the source and drain are doped N+.

18. The gated bodytie field effect transistor of claim 14, wherein the first and second wells are P-wells, wherein the third well is a N-well, and wherein the source and drain are doped P+.

19. The gated bodytie field effect transistor of claim 14, wherein the gated bodytie field effect transistor is processed concurrently with a second transistor on a common wafer, and wherein the second transistor has a gate oxide that is thinner by at least an order of magnitude than the recessed gate oxide of the gated bodytie field effect transistor.

20. A high-voltage extended-drain bodytie field effect transistor, comprising:
a silicon-on-insulator stack comprising a silicon substrate, a buried oxide layer, and a silicon device layer, each having an associated thickness;
a first protruding island and a second protruding island, each having an associated width, wherein a portion of the silicon device layer is left overlaying the buried oxide layer, wherein the first protruding island, at least a center portion of the silicon device layer lying between the first and second protruding islands, and a first portion of the second protruding island are each doped a first-type, and wherein the first portion is nearest the center portion, thereby forming a first-type well, wherein a second portion of the second protruding island is doped a second-type, wherein the second portion is directly adjacent to the first portion, thereby forming a second-type well;
an isolation oxide disposed over the center portion and directly over the buried oxide outside the first and second islands opposite the center portion, thereby surrounding the first and second protruding islands;
a single poly-silicon gate formed over a first portion of the second-type well, over a portion of the first-type well directly adjacent to the second-type well, and over a portion of the isolation oxide overlying the center portion, wherein the single poly-silicon gate includes a thin gate oxide; and
a source and a drain formed in the silicon device layer, wherein the source and drain are doped a first-type and are located at the portions of the first-type well and the second-type well not overlaid by the poly-silicon gate and not overlaid by the center portion of the isolation oxide.

21. The extended-drain bodytie field effect transistor of claim 20, wherein the extended-drain bodytie field effect transistor is processed concurrently with a second transistor on a common wafer, wherein the extended-drain bodytie field effect transistor and the second transistor each have an associated drain region, and wherein the drain region of the second transistor is shorter than the drain region of the extended-drain bodytie field effect transistor, thereby allowing a higher voltage to be dropped across the drain region of the extended-drain bodytie field effect transistor.

22. The extended-drain bodytie field effect transistor of claim 20, wherein the isolation oxide over the center portion, the source, and the drain have upper surfaces that are substantially coplanar with one another.

23. The extended-drain bodytie field effect transistor of claim 20, wherein the isolation oxide over the center portion is approximately 500-1400 Angstroms thick.

24. The extended-drain bodytie field effect transistor of claim 20, wherein the first-type implants are n-type implants and wherein the second-type implants are p-type implants.

25. The extended-drain bodytie field effect transistor of claim 20, wherein the first-type implants are p-type implants and wherein the second-type implants are n-type implants.

26. The extended-drain bodytie field effect transistor of claim 20, wherein a second portion of the second-type well directly adjacent to the first portion of the second-type well is doped first-type.
